(19) United States
(12) Patent Application Publication
(10) Pub. No.: US 2025/0112041 A1
(43) Pub. Date: Apr. 3, 2025

(54) INHERENT AREA SELECTIVE DEPOSITION OF SILICON-CONTAINING DIELECTRIC ON PATTERNED SUBSTRATE

(71) Applicant: Gelest, Inc., Morrisville, PA (US)

(72) Inventors: Chad Michael BRICK, Yardley, PA (US); Tomoyuki OGATA, Yardley, PA (US)

(21) Appl. No.: 18/777,285

(22) Filed: Jul. 18, 2024

Related U.S. Application Data
(60) Provisional application No. 63/527,857, filed on Jul. 20, 2023.

(51) Int. Cl. H01L 21/02

(52) U.S. Cl. CPC H01L 21/0228; H01L 21/02164; H01L 21/02211; H01L 21/02214

(57) ABSTRACT

Processes for the inherently selective formation of silicon-containing films on various substrates are disclosed, which involve the use of precursors containing at least one oxygen atom and at least one silicon-nitrogen bond, and a non-oxidizing plasma.

### CROSS-REFERENCE TO RELATED APPLICATION

This application claims priority to U.S. Provisional Application No. 63/527,857, filed Jul. 20, 2023, the disclosure of which is herein incorporated by reference in its entirety.

### BACKGROUND OF THE INVENTION

For more than a half century, the quest for faster and more powerful electronic devices has driven impressive advances in fabrication methods for creating complicated structures at the micron and nanometer scales. However, the manufacture of today's nanoelectronics relies on increasingly sophisticated and costly patterning techniques that present significant challenges. For instance, variations across processing steps can lead to alignment errors that undermine device performance and reliability, particularly at the back-end-of-line (BEOL) stage. This phase of production faces increasing challenges in the alignment of metal lines and vias as device dimensions shrink, leading to shorting or high resistance. To mitigate this issue, a fully self-aligned via (FSAV) fabrication design, which requires no photolithographic mask alignment step, has been proposed.

One strategy to achieve FSAV is to introduce topographical height differences on metal/low dielectric constant (low-k) material patterns before depositing thin films in the next layer. This approach increases the spacing between vias and metal lines and can be achieved either through metal recess etching or area-selective deposition (ASD) of additional dielectric on top of existing dielectric areas of the substrate. However, metal recessing has some disadvantages, such as multiple process steps, poor uniformity, and surface roughness. ASD, on the other hand, is preferred due to its precise thickness control and excellent surface uniformity. To minimize the effect on interconnect dielectric capacitance, which determines the RC delay of devices, a low-k material such as carbosiloxane (SiOC) or silicon dioxide (SiO₂) is desired to create topography at the BEOL in this FSAV approach. While ASD is a promising strategy to implement FSAV structures, the selective deposition of low-k dielectrics selectively by common deposition techniques such as atomic layer deposition (ALD) or chemical vapor deposition (CVD) poses significant challenges, leading to complicated process schemes for the selective deposition of such films.

Several ASD processes for the selective deposition of oxides on oxide have been reported in the literature such as in U.S. Pat. Nos. 9,895,715; 10,047,435; 10,460,930; 10,510,529; 9,786,491; 9,786,492; 9,425,038; U.S. Patent Application Publication No. 2022/0238323; U.S. Pat. No. 11,898,240, WO 2022/104226, and Yu et al. (Chem. Mater., 33, 902-909 (2021)). In many cases, the reports involve the deposition of high-k dielectrics such as ZnO, Al₂O₃, ZrO₂ or HfO₂, which have limited practical application. Conversely, ASD processes targeting low-k dielectric films such as SiOC or SiO₂ are hampered by the harsh conditions usually required to form silicon-based films, such as oxygen plasma or ozone, which degrade the self-assembled monolayers or small-molecule inhibitors typically used to inhibit growth on the non-targeted areas of the substrate. A small number of reports have resolved this issue by using water-reactive silicon precursors such as chlorosilanes or isocyanatosilanes in combination with chemical blocking agents to passivate the non-growth metallic surfaces. However, the reaction kinetics of these precursors with water is slow, making practical implementation of these processes difficult. Additionally, the use of chemical blocking agents requires additional processing steps to deposit and remove the blocking agent. Furthermore, many semiconductor device layers feature multiple metal surfaces which may require distinct blocking chemistries, further adding process complexity to passivation schemes. While inherent processes for the deposition of SiOCN films at moderate temperatures using reducing plasmas and oxygen-containing precursors are known, the growth rates of the disclosed examples are low and decline with increasing temperatures, limiting the range of film compositions and thicknesses which may be prepared by such methods. Therefore, there remains a need for inherent processes that operate at sufficiently high temperatures for the growth of low-carbon silicon films, which are desirable for many applications.

What is specifically desirable is a simple process with minimal process steps, most preferably only two during each ALD cycle, and the absence or minimization of blocking, blocker removal, and post-deposition cleaning or etching steps, particularly those that must be repeated every ALD cycle or every few cycles.

### SUMMARY OF THE INVENTION

Aspects of the disclosure relate to a method for selectively depositing a silicon-containing dielectric layer upon a patterned substrate, the method comprising:
(a) introducing a patterned substrate into a reaction zone of a deposition chamber, the patterned substrate comprising at least one metallic region and at least one isolated non-metallic region; wherein a temperature of the reaction zone is between about 25° C. and about 500° C.; and
(b) forming a silicon-containing dielectric layer overlaying only the at least one non-metallic region of the patterned substrate via an atomic layer deposition process or a chemical vapor deposition process, wherein the patterned substrate is exposed to a compound having Formula 1, Formula 2, Formula 3, or Formula 4, and wherein the patterned substrate is exposed to a non-oxidizing plasma:

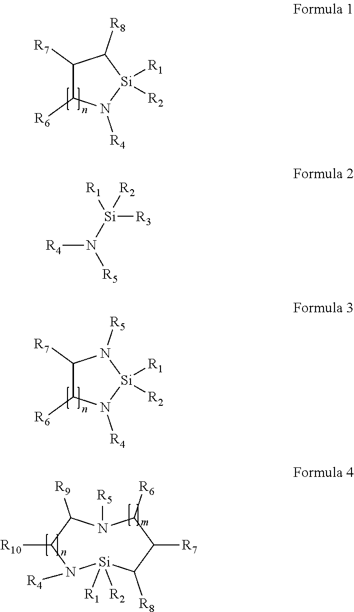

In Formulas 1 to 4, n and m are each independently an integer from 1 to about 4; R₁, R₂, and R₃ are each independently a hydrogen or a linear, branched, or cyclic, optionally substituted, alkoxy, alkyl, aryl, alkyne, alkene, ether, ester, ketone, alkylamino, dialkylamino, alkyl(alkylamino), or alkyl(dialkylamino) group having 1 to about 12 carbon atoms; or a linear, branched, or cyclic, optionally substituted, silyl group having general formula SiR₁₁R₁₂R₁₃, OSiR₁₁R₁₂R₁₃, or R₁₄SiR₁₁R₁₂R₁₃ where R₁₁, R₁₂, and R₁₃ are each independently hydrogen or an alkyl or alkoxy group having about 1 to about 12 carbon atoms (preferably about 1 to about 4 carbon atoms); and R₁₄ an linear or branched alkyl group having 1 to about 12 carbon atoms (preferably about 1 to 4 carbon atoms); R₄ and R₅ are each independently hydrogen; a linear, branched, or cyclic, optionally substituted, alkyl, aryl, alkyne, alkene, ether, ester, ketone, dialkylamino, alkylamino, alkyl(alkylamino), or alkyl(dialkylamino) group having 1 to about 12 carbon atoms; or a linear, branched, or cyclic, optionally substituted, silyl group having general formula SiR₁₁R₁₂R₁₃, or R₁₄SiR₁₁R₁₂R₁₃ where R₁₁, R₁₂, and R₁₃ are each independently hydrogen or an alkyl or alkoxy group having about 1 to about 12 carbon atoms (preferably about 1 to about 4 carbon atoms); and R₁₄ an linear or branched alkyl group having 1 to about 12 carbon atoms (preferably about 1 to 4 carbon atoms); R₆, R₇, R₈, R₉ and R₁₀ are each independently hydrogen or a linear, branched, or cyclic, optionally substituted, alkoxy, alkyl, aryl, alkyne, alkene, ether, ester, ketone, alkylamino, dialkylamino, alkyl(alkylamino), or alkyl(dialkylamino) group having 1 to about 12 carbon atoms; or a linear, branched, or cyclic, optionally substituted, silyl group having general formula SiR₁₁R₁₂R₁₃, OSiR₁₁R₁₂R₁₃ or R₁₄SiR₁₁R₁₂R₁₃ where R₁₁, R₁₂, and R₁₃ are each independently hydrogen or an alkyl or alkoxy group having about 1 to about 12 carbon atoms (preferably about 1 to about 4 carbon atoms); and R₁₄ an linear or branched alkyl group having 1 to about 12 carbon atoms (preferably about 1 to 4 carbon atoms); and at least one of R₁, R₂ and R₃ comprises at least one oxygen atom.

### BRIEF DESCRIPTION OF THE SEVERAL VIEWS OF THE DRAWINGS

The following detailed description of preferred embodiments of the present invention will be better understood when read in conjunction with the appended drawings. For the purposes of illustrating the invention, there is shown in the drawing an embodiment which is presently preferred. It is understood, however, that the invention is not limited to the precise arrangements and instrumentalities shown. In the drawings:

FIG. 1 shows in-situ ellipsometry graphs for the films prepared in Example 1, Comparative Example 1, and Comparative Example 2;

FIG. 2 depicts X-ray photoelectron spectroscopy (XPS) data for the silicon 2s peaks for the films prepared in Example 1, Example 2, and Example 3;

FIG. 3 depicts XPS depth profile data for the film of Comparative Example 3;

FIG. 4 depicts XPS depth profile data for the film of Comparative Example 4;

FIG. 5 depicts XPS depth profile data for the film of Example 5; and

FIG. 6 depicts growth rates for inventive and comparative precursors.

### DETAILED DESCRIPTION OF THE INVENTION

Aspects of the disclosure relate to the use of atomic layer deposition (ALD) or chemical vapor deposition (CVD) processes to selectively deposit silicon-based dielectric layers upon dielectric regions of a patterned substrate. Specifically, described herein are processes for the selective inherent deposition of silicon-based dielectrics on the same or other silicon-based or metal dielectrics utilizing silicon-based precursors that contain both oxygen-containing ligands and nitrogen bonded to silicon in combination with a non-oxidizing plasma.

Unless defined otherwise, all technical and scientific terms used herein have the same meaning as commonly understood to one of ordinary skill in the art to which this invention pertains. Otherwise, certain terms used herein have the meanings as set forth in the specification. All patents, published patent applications and publications cited herein are incorporated by reference as if set forth fully herein.

It must be noted that as used herein and in the appended claims, the singular forms “a,” “an,” and “the” include plural reference unless the context clearly dictates otherwise.

Unless otherwise stated, any numerical value is to be understood as being modified in all instances by the term “about.” Thus, a numerical value typically includes ±10% of the recited value. For example, the recitation of a temperature such as “10° C.” includes 9° C. and 11° C. As used herein, the use of a numerical range expressly includes all possible subranges, all individual numerical values within that range, including integers within such ranges and fractions of the values unless the context clearly indicates otherwise.

For the purposes of this disclosure, the term “overlaying” with reference to the silicon-containing dielectric layer overlaying only the at least one non-metallic region of the patterned substrate may be understood to be synonymous with “covering” or “upon,” i.e., the silicon-containing dielectric layer is positioned overlaying/covering/upon the at least one non-metallic region of the patterned substrate without overlying/covering/being positioned upon the at least one metallic region of the patterned substrate. The terms “isolated” and “separated” are synonymous. The term “overlay” and synonyms thereof may be understood to mean directly or indirectly, i.e., with or without at least one layer between them. The terms “upon” and “on” with respect to formation of the silicon-containing dielectric layer are synonymous.

In one embodiment, the disclosure relates to a method for selectively depositing a silicon-containing dielectric layer upon a patterned substrate, the method comprising:
(a) introducing a patterned substrate into a reaction zone of a deposition chamber, the patterned substrate comprising at least one metallic region and at least one isolated non-metallic region, wherein a temperature of the reaction zone is between about 25° C. and about 500° C.; and
(b) forming a silicon-containing dielectric layer overlaying only the at least one non-metallic region of the patterned substrate via an atomic layer deposition process or a chemical vapor deposition process, wherein the patterned substrate is exposed to a compound having Formula 1, Formula 2, Formula 3, or Formula 4, and wherein the patterned substrate is exposed to a non-oxidizing plasma:

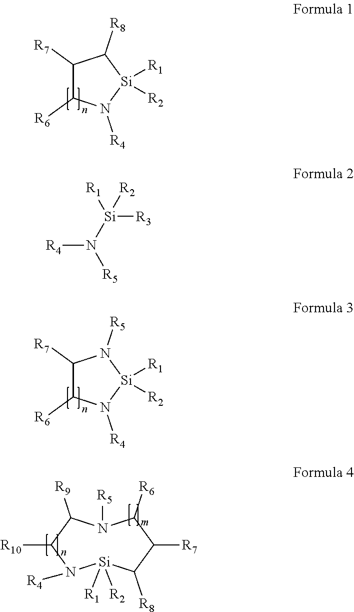

As described in further detail below, in Formulas 1 to 4, n and m are each independently an integer from 1 to about 4; R₁, R₂, and R₃ are each independently a hydrogen or a linear, branched, or cyclic, optionally substituted, alkoxy, alkyl, aryl, alkyne, alkene, ether, ester, ketone, alkylamino, dialkylamino, alkyl(alkylamino), or alkyl(dialkylamino) group having 1 to about 12 carbon atoms; or a linear, branched, or cyclic, optionally substituted, silyl group having general formula SiR₁₁R₁₂R₁₃, OSiR₁₁R₁₂R₁₃, or R₁₄SiR₁₁R₁₂R₁₃ where R₁₁, R₁₂, and R₁₃ are each independently hydrogen or an alkyl or alkoxy group having about 1 to about 12 carbon atoms (preferably about 1 to about 4 carbon atoms); and R₁₄ an linear or branched alkyl group having 1 to about 12 carbon atoms (preferably about 1 to 4 carbon atoms); R₄ and R₅ are each independently hydrogen; a linear, branched, or cyclic, optionally substituted, alkyl, aryl, alkyne, alkene, ether, ester, ketone, alkylamino, dialkylamino, alkyl(alkylamino), or alkyl(dialkylamino) group having 1 to about 12 carbon atoms; or a linear, branched, or cyclic, optionally substituted, silyl group having general formula SiR₁₁R₁₂R₁₃ or R₁₄SiR₁₁R₁₂R₁₃ where R₁₁, R₁₂, and R₁₃ are each independently hydrogen or an alkyl or alkoxy group having about 1 to about 12 carbon atoms (preferably about 1 to about 4 carbon atoms); and R₁₄ an linear or branched alkyl group having 1 to about 12 carbon atoms (preferably about 1 to 4 carbon atoms); R₆, R₇, R₈, R₉ and R₁₀ are each independently hydrogen or a linear, branched, or cyclic, optionally substituted, alkoxy, alkyl, aryl, alkyne, alkene, ether, ester, ketone, alkylamino, dialkylamino, alkyl(alkylamino), or alkyl(dialkylamino) group having 1 to about 12 carbon atoms; or a linear, branched, or cyclic, optionally substituted, silyl group having general formula SiR₁₁R₁₂R₁₃, OSiR₁₁R₁₂R₁₃ or R₁₄SiR₁₁R₁₂R₁₃ where R₁₁, R₁₂, and R₁₃ are each independently hydrogen or an alkyl or alkoxy group having about 1 to about 12 carbon atoms (preferably about 1 to about 4 carbon atoms); and R₁₄ an linear or branched alkyl group having 1 to about 12 carbon atoms (preferably about 1 to 4 carbon atoms); and at least one of R₁, R₂ and R₃ comprises at least one oxygen atom. Notably, each of the compounds having Formula 1, 2, 3, or 4 has a silicon-nitrogen bond; there is no hydrocarbon or other spacer or linker group between the silicon and nitrogen.

In one embodiment, the disclosure specifically relates to a method for selectively depositing a dielectric layer upon an existing non-metallic layer of a patterned substrate by employing an atomic layer deposition process, the method comprising:
(a) introducing a patterned substrate into a reaction zone of a deposition chamber, the patterned substrate comprising at least one metallic region and at least one isolated non-metallic region, wherein a temperature of the reaction zone is between about 25° C. and about 500° C.;
(b0.1) optionally performing an anneal, clean, etch, or plasma treatment on the patterned substrate;
(b0.2) optionally exposing the patterned substrate to an oxidant; (b0.3) optionally exposing the patterned substrate to a chemical blocking agent that selectively passivates at least one region of the substrate;
(b1) exposing the patterned substrate to a pulse of a compound having Formula 1, Formula 2, Formula 3, or Formula 4;
(b2) purging the deposition chamber;
(b3) exposing the patterned substrate to a non-oxidizing plasma;
(b4) purging the deposition chamber;
(b4.1) optionally exposing the patterned substrate to an oxidant;
(b4.2) optionally purging the deposition chamber;
(b5) repeating steps (b1) through (b4.2) until a desired film thickness is reached;
(b5.1) optionally performing an anneal, clean, etch, or plasma treatment on the patterned substrate;
(b5.2) optionally exposing the patterned substrate to an oxidant;
(b5.3) optionally exposing the patterned substrate to a chemical blocking agent to selectively passivate at least one regio of the substrate;
(b5.4) optionally purging the reaction chamber; and
(b.6) optionally repeating steps (b1) through (b5.4) until a desired silicon-containing dielectric layer thickness is reached. The silicon-containing dielectric layer overlays only the at least one non-metallic region of the patterned substrate.

Each of these steps will be described in further detail below. In this method, steps (a) through (b0.3) represent pre-deposition surface preparation, steps (b1) through (b5) represent an ALD deposition process, and steps (b5.1) through (b6) represent a super-cycle ALD process which periodically includes an extra surface cleaning or modification process in order to enhance selectivity by re-establishing appropriate growth and non-growth surfaces or removing undesired growth on the non-growth surfaces, or in order to modify the properties of the growing film or its interface with adjacent layers.

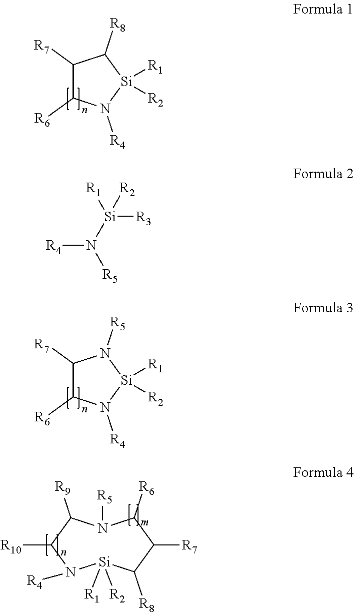

In Formulas 1 to 4, n and m are each independently an integer from 1 to about 4; R₁, R₂, and R₃ are each independently a hydrogen or a linear, branched, or cyclic, optionally substituted, alkoxy, alkyl, aryl, alkyne, alkene, ether, ester, ketone, alkylamino, dialkylamino, alkyl(alkylamino), or alkyl(dialkylamino) group having 1 to about 12 carbon atoms (preferably about 1 to about 4 carbon atoms); or a linear, branched, or cyclic, optionally substituted, silyl group having general formula SiR₁₁R₁₂R₁₃, OSiR₁₁R₁₂R₁₃ or R₁₄SiR₁₁R₁₂R₁₃ where R₁₁, R₁₂, and R₁₃ are each independently hydrogen or an alkyl or alkoxy group having about 1 to about 12 carbon atoms (preferably about 1 to about 4 carbon atoms); and R₁₄ an linear or branched alkyl group having 1 to about 12 carbon atoms (preferably about 1 to 4 carbon atoms); R₄ and R₅ are each independently hydrogen; a linear, branched, or cyclic, optionally substituted, alkyl, aryl, alkyne, alkene, ether, ester, ketone, alkylamino, dialkylamino, alkyl(alkylamino), or alkyl(dialkylamino) group having 1 to about 12 carbon atoms (preferably about 1 to about 4 carbon atoms); or a linear, branched, or cyclic, optionally substituted, silyl group having general formula SiR₁₁R₁₂R₁₃ or R₁₄SiR₁₁R₁₂R₁₃ where R₁₁, R₁₂, and R₁₃ are each independently hydrogen or an alkyl or alkoxy group having about 1 to about 12 carbon atoms (preferably about 1 to about 4 carbon atoms); and R₁₄ an linear or branched alkyl group having 1 to about 12 carbon atoms (preferably about 1 to 4 carbon atoms); R₆, R₇, R₈, R₉ and R₁₀ are each independently hydrogen or a linear, branched, or cyclic, optionally substituted, alkoxy, alkyl, aryl, alkyne, alkene, ether, ester, ketone, alkylamino, dialkylamino, alkyl(alkylamino), or alkyl(dialkylamino) group having 1 to about 12 carbon atoms (preferably about 1 to about 4 carbon atoms), or a linear, branched, or cyclic, optionally substituted, silyl group having general formula SiR₁₁R₁₂R₁₃, OSiR₁₁R₁₂R₁₃ or R₁₄SiR₁₁R₁₂R₁₃ where R₁, R₁₂, and R₁₃ are each independently hydrogen or an alkyl or alkoxy group having about 1 to about 12 carbon atoms (preferably about 1 to about 4 carbon atoms); and R₁₄ an linear or branched alkyl group having 1 to about 12 carbon atoms (preferably about 1 to 4 carbon atoms); and at least one of R₁, R₂ and R₃ comprises at least one oxygen atom. Preferably, at least one of R₁, R₂, and R₃ is an alkoxy group. If substituted, any of the R groups may be substituted with any known substituents, including, without limitation, halogens, amino, alkylamino, dialkylamino, alkyl(alkylamino), and alkyl(dialkylamino), and silyl groups as previously described, each of which may be optionally substituted.

In preferred embodiments, n and m are each 1; R₁, R₂, and R₃ are alkyl, alkoxy, ester, ether, or dialkylamino groups, R₄ is alkyl, alkenyl, alkyl(dialkylamino), or silyl; R₅ is hydrogen or alkyl; R₆, R₇, and R₅ are hydrogen or alkyl, and R₉ and R₁₀ are hydrogen.

A method according to the disclosure involves introducing a patterned substrate into a reaction zone of a deposition chamber, the patterned substrate comprising at least one metallic region and at least one isolated non-metallic region; wherein a temperature of the reaction zone is between about 25° C. and about 500° C.; and exposing the patterned substrate to the following sequence of steps which are repeated as many times as necessary to achieve the desired film thickness: exposing the patterned substrate to a pulse of a compound having Formula 1, Formula 2, Formula 3, or Formula 4, purging the deposition chamber, exposing the patterned substrate to non-oxidizing plasma, and purging the deposition chamber. The resulting silicon-based dielectric layer selectively forms upon non-metallic regions or areas of the patterned substrate so that is overlays only the non-metallic region(s) of the patterned substrate. For the purposes of this disclosure, the terms “layer” and “film” may be understood to be synonymous.

A variety of different types of patterned substrates are appropriate for use in the method described herein, provided that they contain both non-metallic and metallic regions. The term “patterned substrate” should be understood to refer to a substrate with at least two isolated or separated surface regions of differing materials. Appropriate non-metallic substrate regions include, without limitation, the presently preferred silicon dioxide, silicon oxycarbide, silicon oxynitride, silicon carboxynitride, silicon oxyfluoride, and borosilicate. Other possible substrates which would be appropriate include, without limitation, substrates containing non-metallic regions comprising silicon, germanium, silicon-germanium alloy, silicon nitride, titanium nitride, tantalum nitride, aluminum oxide, hafnium dioxide, titanium dioxide, and/or zinc oxide. Appropriate metallic substrates regions include the presently preferred copper and cobalt as well as, without limitation, tungsten, ruthenium, gold, and/or molybdenum.

The term “substrate” as used herein is used to describe the material surface on which film processing is performed during the manufacturing process. For example, a substrate may comprise a bulk layer of silicon, silicon dioxide, silicon-on-insulator, strained silicon, doped silicon, germanium, gallium arsenide, silicon carbide, glass, alumina, metals or metal nitrides depending on the application. In addition to the bulk layer, the substrate may contain multiple layers of patterned thin films that form a device. The exposed surfaces of the outermost layers comprise the substrate, which must include at least one non-metallic growth surface and at least one metallic non-growth surface according to the present invention.

In the initial step, the reaction zone of the deposition chamber is heated or cooled to about 25° C. to about 500° C., inclusive, so that all temperatures within this range are included. The reaction zone may be heated prior to or after introduction of the substrate to the reaction chamber. Preferred temperatures for the reaction zone are about 275° C. to about 425° C., including all temperatures within this range, such as about 275° C., about 300° C., about 325° C., about 350° C., about 375° C., about 400° C., and about 425° C., including all intervening temperatures.

The parameters of the purge cycles are not particularly limited, and may be optimized based on the specific reaction conditions, apparatus, and reactants. Generally, any inert gas such as argon or nitrogen may be employed; typical purge cycles are at least about 2 seconds long. In preferred embodiments, the purges are about 10 seconds.

The temperatures of the substrate and the reaction zone of the deposition chamber are critical for producing the desired silicon-based dielectric layer on the patterned substrate. Specifically, the temperatures of the substrate and of the reaction zone in the deposition chamber during exposure to the pulses of the compound having Formula 1, 2, 3, or 4 and the optional water, as described below, are preferably about 25° C. to about 500° C., more preferably about 275° C. to about 425° C. It may be understood that the ranges of substrate temperatures are inclusive of all temperatures within the range, so that temperatures of about 275° C. to about 425° C. include temperatures such as about 300° C., about 325° C., about 350° C., about 375° C., about 400° C., and all intervening temperatures including, without limitation, about 275° C., about 280° C., about 285° C., about 290° C., about 295° C., about 300° C., about 305° C., about 310° C., about 315° C., about 320° C., about 325° C., about 330° C., about 335° C., about 340° C., about 345° C., about 350° C., about 355° C., about 360° C., about 365° C., about 370° C., about 375° C., about 380° C., about 385° C., about 390° C., about 395° C., about 400° C., about 405° C., about 410° C., about 415° C., about 420° C., and about 425° C., and all intervening temperatures.

It is within the scope of the disclosure for the temperatures of the substrate and the reaction zone of the deposition chamber to be the same or different. That is, it is possible to heat the substrate chuck or platen independently of the chamber, and these temperatures may be independently controlled by the deposition tool. It is possible to raise the substrate temperature even higher than the main part of the chamber, however, these gaps are typically minor (about 10° C. to about 30° C.). Therefore, the ranges described above are applicable to both the substrate and the reaction zone. It is understood in the art that in ALD, these are effectively the same, as the desired reactions occur on the substrate surface. In CVD, however, reactions take place both in the gas phase in the main chamber space and on the substrate surface. In that case, a temperature differential between that of the gas phase reactions and the surface reactions can be introduced.

The pulse lengths of each reactant may also be optimized based on the specific reaction conditions and apparatus and are generally kept as short as practical. The pulse length for the compound having Formula 1, 2, 3, or 4 is about 0.05 to about 30 seconds, preferably 2 to about 15 seconds, more preferably at least about 3 seconds and more preferably about 5 seconds to about 10 seconds. The pulse length for the optional water pulses is about 2 to about 15 seconds, preferably about 5 to about 10 seconds. While longer pulse times may be effective for all compounds, they are not practical from a materials consumption or tool utilization standpoint.

Optionally, prior to exposing the substrate to the compound having Formula 1, 2, 3, or 4, it is within the scope of the disclosure to perform an annealing, cleaning, etching, or plasma treatment of the patterned substrate. For example, the substrate may be washed with ethanol for about five minutes before being placed into the deposition chamber at the desired deposition temperature and then treated with about one minute of nitrogen plasma via remote ICP for 60 seconds at a power of 2500 W before initiation of the deposition process. While not limiting, other examples of wet pre-treatment protocols that may be appropriate depending on the nature of the growth and non-growth surfaces of the patterned substrate include washes or etches with organic solvents such as isopropanol or tetrahydrofuran, organic acids such as citric acid or acetic acid, mineral acids such as hydrogen fluoride, hydrogen chloride, or sulfuric acid, bases such as ammonia, or oxidizers such as hydrogen peroxide, alone, as mixtures, or in sequential combination, as is known in the art. Dry processes that may be used as pre-treatments include annealing steps in the same or different chamber which may comprise either reducing or oxidizing conditions, reactive ion etch, or plasma treatment. It may be understood that more than one pre-treatment may be applied to the same patterned substrate as appropriate for the specific regions of the patterned substrate. Other similar substrate pre-treatment processes which are known in the art would also be applicable. Such treatments may improve the selectivity of the inventive process or performance of the resulting films, but the appropriate pretreatment method and conditions may be determined on a case-to-case basis depending on the specific substrate, apparatus, reactants, and reaction conditions.

Optionally, prior to exposing the patterned substrate to a pulse of a compound having Formula 1, 2, 3, or 4, the patterned substrate is exposed to a chemical blocking agent that selectively passivates one or more regions of the substrate. If such an optional step is performed, the chemical blocking agent may be removed once the desired dielectric film thickness has been achieved. Inhibitor compounds that may be used include, without limitation, polymers, N-heterocyclic carbenes, silanes, or organic or organosilane thiols, amines, aldehydes, ketones, phenols, and phosphonic acids, which may be removed by dry processes not limited to plasma etching, reactive ion etching, corona treatment, ozonolysis, UV/ozone, thermal decomposition or thermal desorption, or wet etching processes utilizing formulations comprising organic solvents, acid, base, or hydrogen peroxide.

For the purposes of this disclosure, the phrase “non-oxidizing plasma” may be understood to mean a plasma generated using a gas mixture containing no more than one volume percent of oxygen-containing species excluding the silicon precursor. Examples of such oxygen-containing species that may be intentionally or inadvertently added to the plasma stream include oxygen, water, carbon dioxide or nitrous oxide, preferably in an amount of less than about 1 volume %. In preferred embodiments, the plasma comprises hydrogen, nitrogen, ammonia, or hydrazine with argon as a carrier gas, delivered by a remote inductively-coupled plasma (ICP) system. However, it is within the scope of the disclosure to use other forms of plasma generation such as capacitively coupled plasma or hollow cathode plasma. Most preferably, the plasma comprises nitrogen with argon as a carrier gas.

Exposure of the patterned substrate to the non-oxidizing plasma may occur either sequentially or simultaneously with respect to the exposure to the silicon-containing compound of Formula 1, 2, 3 or 4. In the case of alternating exposure of silicon compound and plasma, generally referred to plasma-enhanced atomic layer deposition (PEALD), the duration of the plasma exposure is preferably about 1 to 60 seconds and most preferably about 10 to 20 seconds. Additional or extended pulses of plasma may be added before the deposition process to clean or otherwise prepare the surface, or added after the deposition process to clean or otherwise prepare the surface for subsequent processes in the manufacture of the desired semiconductor device. Within the scope of this disclosure, it may be understood that the term “pulse” includes both temporal and spatial methods of exposing the patterned substrate to the chemical compound of Formula 1, Formula 2, Formula 3, or Formula 4 and the non-oxidizing plasma in a sequential manner. While not limiting, examples of appropriate methods of pulsing the inventive chemical compounds of Formula 1, Formula 2, Formula 3, and Formula 4 include open vacuum systems in which the precursor container, reaction chamber, and pumping system are connected throughout the pulse, closed vacuum systems in which the pumping system is isolated from the reaction chamber during part or all of the pulse, inducing a dwell time for the chemical precursor in the reaction chamber, or systems which create exposures to the chemical compounds of Formula 1, Formula 2, Formula 3, or Formula 4 by physically moving the patterned substrate from regions of space where the chemical compounds are present to areas where they are not, commonly referred to as “Spatial ALD.” It should also be understood that pulses of the non-oxidizing plasma may be implemented by either temporal or spatial methods.

In the case of simultaneous exposure of the substrate to precursor and plasma, generally referred to as plasma-enhanced chemical vapor deposition (PECVD), the duration of the process is determined by the growth rate of the process under the specific conditions being utilized and the desired thickness of the deposited film. It may be understood that it is within the scope of the disclosure that the PECVD process involves both cases in which the plasma and precursor introduction start and end simultaneously, and cases in which either one starts before or ends after the other. Additionally, the PECVD process within the scope of the disclosure may consist of a single exposure to precursor and plasma, or a series of shorter exposures divided by purges of the reaction zone by inert gases or cleans, etches, anneals or additional plasma treatments of the patterned substrate, referred to as “Pulsed PECVD.”

The duration of the plasma exposure is preferably about 1 to about 300 seconds per nanometer of film growth, more preferably about 5 to about 100 seconds. It is well understood in the art that the “per nanometer of film growth” is important in a CVD process, because unlike ALD, in which film thickness is controlled by the number of repeated cycles, in CVD the thickness is controlled by time. CVD is generally a linear process, so the thickness of a film may be doubled by doubling the length of the process.

In some embodiments, following the exposure to non-oxidizing plasma and purge, the patterned substrate is exposed to a pulse of an oxidant, followed by a purge step as previously described. For purposes of this disclosure, the term “oxidant” may be understood to include water, carbon dioxide, nitrous oxide, oxygen, ozone, hydrogen peroxide, alcohols, mixtures thereof, and plasmas thereof. While not limited by theory, the optional addition of an oxidant pulses between the pulse of non-oxidizing plasma and the pulse of a chemical compound of Formula 1, Formula 2, Formula 3, or Formula 4 may increase the concentration of hydroxide groups on the surface of the deposited dielectric film, which affords greater adsorption of the chemical compound of Formula 1, Formula 2, Formula 3, or Formula 4 during its subsequent pulse. The pulse length for the optional oxidant pulses is about 0.5 to about 15 seconds, preferably about 5 to about 10 seconds.

In some embodiments, after a number of Formula 1, 2, 3, or 4 compound exposure/purge/non-oxidizing plasma exposure/purge sequences (optionally including oxidant exposure/purge steps), (such as about 1 to about 50 sequences) have been completed, the substate is subjected to an annealing, cleaning, etching, or plasma treatment as previously described, as well as an optional exposure to a chemical blocking agent as previously described.

It is within the scope of the disclosure to prepare silicon-containing dielectric films having thicknesses of about 1 to 20 nm, particularly about 3 nm to 10 nm, which thicknesses are currently desirable in the microelectronic industry. The desired film or layer thickness may be achieved by repeating the method steps described herein repeatedly.

It is further within the scope of the disclosure to move the chemical compounds of Formula 1, Formula 2, Formula 3, and Formula 4 in a carrier gas. Without limitation, any noble gas, such as argon, or inert gas, such as nitrogen, would be appropriate. However, it is also within the scope of the disclosure not to employ a carrier gas. It is also within the scope of the disclosure to dilute the reactive plasma gases such as nitrogen, hydrogen, ammonia or hydrazine with carrier gases such as argon or helium.

The compounds having Formulas 1, 2, 3, and 4 are silicon compounds which contain at least one silicon-nitrogen (Si—N) bond, which provides the rapid surface reactivity that is necessary for an ALD process, and at least one oxygen-containing ligand attached to a silicon atom, such as the presently preferred alkoxy group, which acts as an oxygen source. While not limiting, exemplary compounds include mixed alkoxy-amino silanes or cyclic azasilanes or diazasilanes with at least one alkoxy group bound to the silicon.

Specific examples of silicon compounds within the scope of the disclosure include N-ethyl-2,2-dimethoxy-4-methyl-1-aza-2-silacyclopentane, N-n-butyl-aza-2,2-dimethoxysilacyclopentane, N-t-butyl-aza-2,2-dimethoxysilacyclopentane, N-methyl-aza-2,2-dimethoxysilacyclopentane, 2,2-dimethoxy-1,3-dimethyl-1,3-diaza-2-silacyclopentane, 2,2-diethoxy-1,3-dimethyl-1,3-diaza-2-silacyclopentane, (1-(3-triethoxysilyl)propyl)-2,2-diethoxy-1-aza-2-silacyclopentane, N-allyl-aza-2,2-dimethoxysilacyclopentane, 2,2-dimethoxy-1,6-diaza-2-silacyclooctane, aza-2-methyl-2-methoxysilacyclopentane, N-methyl-2-methyl-2-methoxy-4-methyl-1-aza-2-silacyclopentane, (dimethylamino)trimethoxysilane, (diethylamino)trimethoxysilane, (diethylamino)triethoxysilane, (dimethylamino)triethoxysilane, (diisopropoxyamino)trimethoxysilane, or (diisopropoxyamino)triethoxysilane, bis(dimethylamino)dimethoxysilane, bis(dimethylamino)diethoxysilane, tris(dimethylamino)methoxysilane, tris(dimethylamino)ethoxysilane, 3-[(dimethylamino)dimethylsilyl]propyl 2-methyl-2-propenoate, 2-(ethoxymethyl)-1-(trimethylsilyl)-1-aza-2-silacyclopentane, 1-(3-methoxypropyl)-N,N,1,1-tetramethylsilanamine, or N-methyl-2,2-dimethoxy-4-trimethylsilyl-1-aza-2-silacyclopentane, or 2-methoxy-1-(trimethylsilyl)-2-[(trimethylsilyl)oxy]-1-aza-2-silacyclopentane, whose chemical structures are shown below.

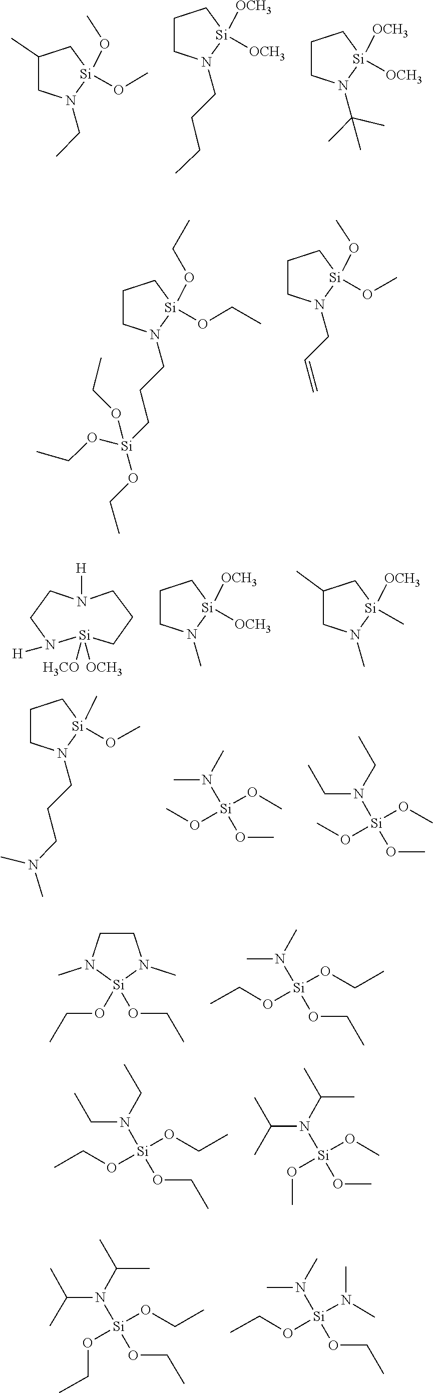

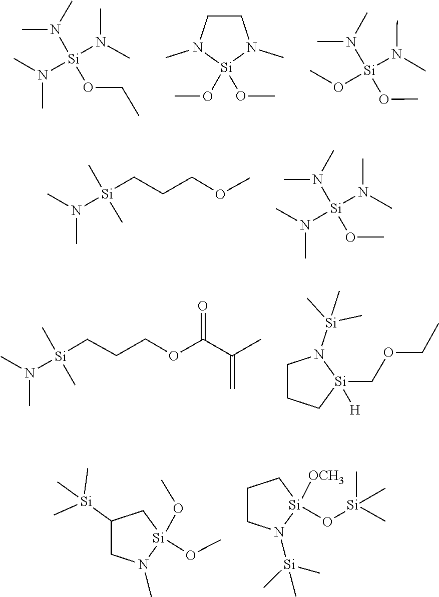

The silicon compounds according to the present disclosure are preferably substantially free of halides, metals, and metal ions. “Substantially free” as used herein in relation to halides, such as for example, chloride, bromide, iodide, or fluoride, means less than about 3 ppm by weight of the halide as determined by inductively coupled plasma mass spectrometry (ICP-MS) or ion chromatography, and more preferably less than about 1 ppm of halide. With respect to metals and metal ions, “substantially free” is used herein to mean less than about 1 ppm of ionic or neutral forms of lithium, sodium, magnesium, potassium, calcium, scandium, titanium, vanadium, chromium, manganese, iron, cobalt, nickel, copper, zinc or other transition metals of higher molecular mass, and more preferably less than about 0.1 ppm of ionic or neutral metals.

The process described herein is an inherently selective process. “Inherent” as used herein means that no modification of the non-growth metal surfaces by organic molecules is required to suppress growth on at least one metal surface during the deposition process. However, it is within the scope of the disclosure that small molecules, self-assembled monolayers, or polymers known in the art could be used to further enhance the selectivity of the process by suppressing growth on one or more non-growth surfaces. Such molecules known in the art include C1-C18 thiols such as dodecanethiol, C1-C18 silanes such as dodecylsilane, benzimidazolium N-heterocyclic carbenes, imidazolium N-heterocyclic carbenes, ketones such as acetylacetone, phenols such as catechol, C1-C18 phosphonic acids such as octadecylphosphonic acid, amines such as aniline, and cyclic azasilanes such as N-methyl-aza-2,2,4-trimethylsilacyclopentanes. Such polymers known in the art include, without limitation, polyimides, polynorbornenes, and polyacrylates.

In a further aspect of the disclosure, a method for selectively depositing a dielectric layer upon an existing non-metallic layer of a patterned substrate by employing a chemical vapor deposition (CVD) process or a pulsed chemical vapor deposition process comprises:
(a) introducing a patterned substrate into a reaction zone of a deposition chamber, the patterned substrate comprising at least one metallic region and at least one isolated non-metallic region, wherein a temperature of the reaction zone is between about 25° C. and about 500° C.;
(b0.1) optionally performing an anneal, clean, etch, or plasma treatment on the substrate;
(b0.2) optionally exposing the patterned substrate to an oxidant;
(b0.3) optionally exposing the patterned substrate to a chemical blocking agent to selectively passivate at least one region of the substrate;
(b7) exposing the patterned substrate to a compound of Formula 1, Formula 2, Formula 3, or Formula 4 while simultaneously exposing the patterned substrate to a non-oxidizing plasma;
(b8) optionally purging the deposition chamber;
(b8.1) optionally performing an anneal, clean, etch, or plasma treatment on the patterned substrate;
(b8.2) optionally exposing the patterned substrate to an oxidant;
(b8.3) optionally exposing the patterned substrate to a chemical blocking agent to selectively passivate at least one region of the substrate;
(b8.4) optionally purging the reaction chamber; and
(b9) repeating steps (b7) through (b8.4) until a desired film thickness is reached.

The silicon-containing dielectric layer overlays only the at least one region of the patterned substrate.

The compounds having Formulas 1, 2, 3, and 4 have been described previously.

Most of the steps of this method have been described previously with the exception of step (d), which involves exposure to the Formula 1, 2, 3, or 4 compound and the non-oxidizing plasma described previously. This simultaneous exposure to the chemical compound of Formula 1, 2, 3 or 4 and plasma may be continued without interruption until the desired layer/film thickness is reached, or stopped and restarted multiple times in order to include cleans, anneals, etches or plasma treatments of the patterned substrate with film deposited thereon within the process of growing the target film. While the exposure to the compound of Formula 1, 2, 3, or 4 and the plasma are simultaneous, it should be understood that within the scope of this disclosure that either exposure may start before or end after the other.

In this method, steps (a) through (b0.3) represent pre-deposition surface preparation, steps (b7) through (b8) represent a CVD or pulsed CVD deposition process, and steps (b8.1) through (b9) represent a super-cycle CVD or super-cycle pulsed CVD process which periodically includes an extra surface cleaning or modification process in order to enhance selectivity by re-establishing appropriate growth and non-growth surfaces or removing undesired growth on the non-growth surfaces, or in order to modify the properties of the growing film or its interface with adjacent layers.

In some embodiments, the inventive precursor compounds may be used in an ALD or CVD process to form a dielectric layer on a dielectric layer of a patterned substrate in an inherently selective manner. In some embodiments, the term “selectively” means that the deposited film forms on the target growth surface at a rate greater than or equal to at least five times or preferably ten times or even more preferably twenty or more times than it deposits on untargeted non-growth surfaces. As used herein, an “inherently” selective process is one where no modification of some or all of the non-growth surfaces by growth-inhibiting small molecule inhibitors, self-assembled monolayers, or polymeric films is required to achieve the selective growth on dielectric layers. However, it is within the scope of this invention that one or more of the non-growth areas be modified by such blocking agents such as small molecule inhibitors, self-assembled monolayers, or polymeric films in order to achieve enhanced selectivity. Examples of such materials known in the art include chlorosilanes, alkoxysilanes, aminosilanes, cyclic azasilanes, alkane thiols, alkane phosphoric acids, phenols, organic acids, alkynes, alkenes, aldehydes and ketones. The blocking agent may be applied before the ALD or CVD process is initiated or one or more times during the middle of the ALD or CVD process, or both, in order to achieve optimize selectivity with respect to all growth and non-growth surfaces found on the substrate.

As used herein, the terms “growth” and “non-growth” shall be understood to refer to areas of a patterned substrate where dielectric film growth is desired and not desired, respectively, for the fabrication of a device structure. According to the present invention, at least one growth surface must be a non-metal. Non-limiting examples of growth surfaces include silicon dioxide, silicon, silicon-germanium, alumina, germanium, SiOC low-k dielectrics, silicon nitride and silicon carbide. Non-limiting examples of exemplary materials that may be a non-growth surface include copper, cobalt, ruthenium, molybdenum, and tungsten.

The terms “atomic layer deposition” or “ALD” may be understood to mean a temporal process by which a compound of Formula 1, 2, 3 or 4 is introduced to a reaction chamber containing the substrate for a set period of time, the reaction chamber purged with an inert gas such as nitrogen, argon or helium, the substrate exposed a second reactant or plasma for a set period of time, and the reaction chamber again purged with an inert gas. This cycle of four steps is then repeated until the desired film thickness is reached. Alternatively, “atomic layer deposition” or “ALD” may be understood to mean a spatial process, where the substrate is alternatively moved from a location containing the Formula 1, 2, 3, or 4 compound and a location containing the second reactant or plasma, a process that is repeated until the desired film thickness is achieved.

The terms “chemical vapor deposition” or “CVD” shall be understood to mean a process by which according to the present invention a Formula 1, 2, 3, or 4 compound is introduced to a reaction chamber simultaneously with a second reactant or plasma, and continued until a desired film thickness is reached.

According to the present invention, both ALD and CVD processes shall be understood that the substrate may be exposed to one or more pretreatment processes in the same or different tool before initiation of the ALD or CVD process. These pretreatment processes may include wet or plasma etch, polish, solvent wash, hydroxylation, oxidation, reduction, anneal, or UV or e-beam exposure. It shall also be understood that the pretreatment processes may optionally include the use of a blocking agent such as a small molecule inhibitor, self-assembled monolayer, or polymeric film to suppress growth on one or more non-growth surfaces.

The ALD and CVD processes according to this invention may occur one time or more than one time. If more than one time, processes including wet or plasma etch, polish, solvent wash, hydroxylation, oxidation, reduction, anneal, and UV or e-beam exposure may be performed between ALD and CVD processes. Furthermore, processes including wet or plasma etch, polish, solvent wash, hydroxylation, oxidation, reduction, anneal, and UV or e-beam exposure may be implemented after the final ALD or CVD process in order to remove undesired film growth on non-growth surfaces, particles, or contaminants, chemically or physically transform the deposited materials, or prepare the substrate surface for further device fabrication steps.

The precursors described herein comprise two essential elements: the presence of at least one oxygen atom in the precursor's chemical structure, which is necessary to provide an oxygen source for the formation of the silicon-containing dielectric films, and a silicon-nitrogen bond, which allows rapid, strong bonding to the growing film surface which persists for relevant at temperatures up to 500° C.

The high growth rate and general applicability of these precursors at temperatures above about 200° C. allows for the formation of films with low carbon and nitrogen content. While SiOC(N) films are desirable in some applications, in many others, films with little or no carbon or nitrogen (for example, silicon dioxide) are preferred.

The invention will now be described in connection with the following, non-limiting examples.

The chemical precursor used in Example 1, Example 3, Example 4, Comparative Example 2, Comparative Example 3, and Comparative Example 4 was N-ethyl-2,2-dimethoxy-4-methyl-1-aza-2-silacyclopentane, having the following structure:

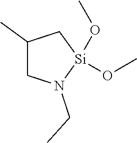

The chemical precursor used in Comparative Example 1 was N-methyl-aza-2,2,4-trimethylsilacyclopentane. having the following structure:

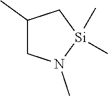

The chemical precursor used in Example 2, Example 5, Example 6, and Example 7 was (dimethylamino)trimethoxysilane having the following structure:

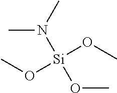

### Example 1: Selective Growth of SiO₂ on SiO₂ Using N-ethyl-2,2-dimethoxy-4-methyl-1-aza-2-silacyclopentane

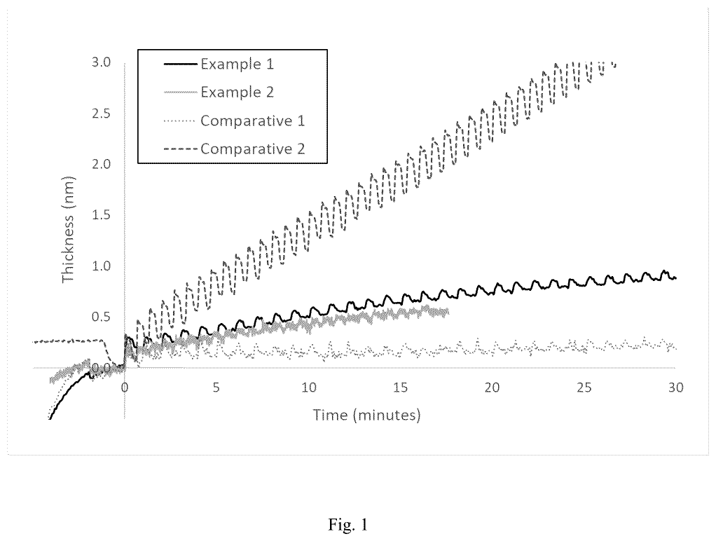

A silicon wafer with 1000 nm of thermal oxide was placed in a reaction chamber at 400° C. The wafer was exposed to one minute of nitrogen plasma, and then 125 ALD cycles of sequential exposures to N-ethyl-2,2-dimethoxy-4-methyl-1-aza-2-silacyclopentane (10 seconds), nitrogen plasma (10 seconds), and water (10 seconds) separated by 10 second purges. A silicon dioxide film of 2.0 nm was grown on top of the underlying thermal oxide as determined by ellipsometry (see FIG. 1).

### Example 2: Selective Growth of SiO₂ on SiO₂ Using (Dimethylamino)trimethoxysilane

A silicon wafer with 1000 nm of thermal oxide was placed in a reaction chamber at 300° C. The wafer was exposed to one minute of nitrogen plasma, and then 25 ALD cycles of sequential exposures to (dimethylamino)trimethoxysilane (5 seconds) and nitrogen plasma (10 seconds) separated by 10 second purges. A silicon dioxide film of 0.6 nm was grown on top of the underlying thermal oxide as determined by ellipsometry (see FIG. 1).

### Example 3: Selective Non-growth of SiO₂ on Copper Using N-ethyl-2,2-dimethoxy-4-methyl-1-aza-2-silacyclopentane

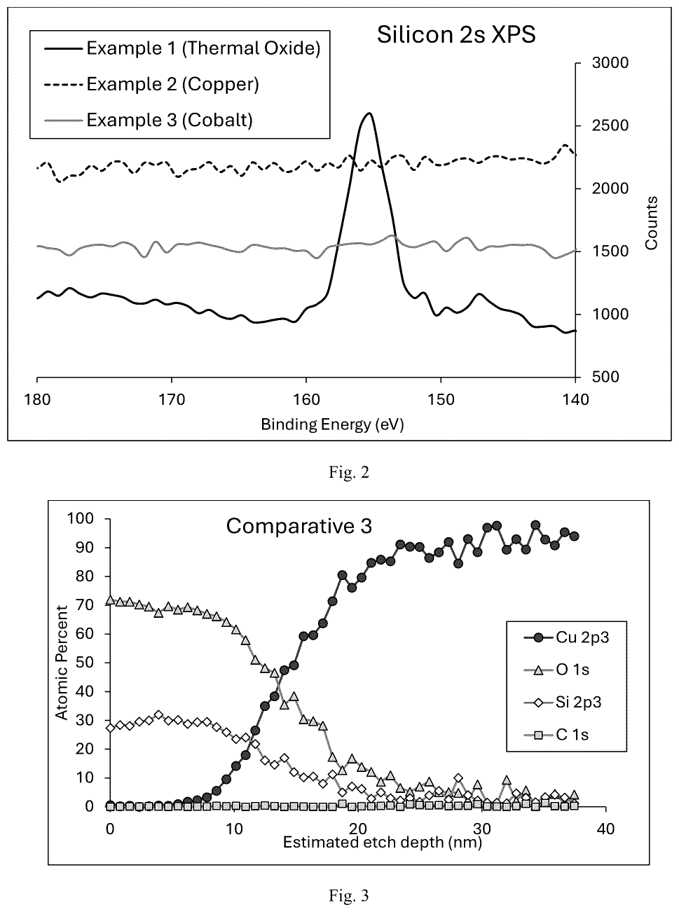

A silicon wafer with 500 nm of physically vapor deposited (PVD) copper was washed with ethanol for five minutes and then placed in a reaction chamber at 400° C. The wafer was exposed to one minute of nitrogen plasma, and then 125 ALD cycles of sequential exposures to N-ethyl-2,2-dimethoxy-4-methyl-1-aza-2-silacyclopentane (10 seconds), nitrogen plasma (10 seconds), and water (10 seconds) separated by 10 second purges. No silicon signal was detected by X-ray photoelectron spectroscopy (XPS) (see FIG. 2).

### Example 4: Selective Non-Growth of SiO₂ on Cobalt Using N-ethyl-2,2-dimethoxy-4-methyl-1-aza-2-silacyclopentane

A silicon wafer with 50 nm of physically vapor deposited (PVD) cobalt was placed in a reaction chamber at 400° C. The wafer was exposed to one minute of nitrogen plasma, and then 125 ALD cycles of sequential exposures to N-ethyl-2,2-dimethoxy-4-methyl-1-aza-2-silacyclopentane (10 seconds), nitrogen plasma (10 seconds), and water (10 seconds) separated by 10 second purges. No silicon signal was detected by XPS (see FIG. 2).

### Example 5: Selective Non-Growth of SiO₂ on Copper Using (Dimethylamino)trimethoxysilane

A silicon wafer with 500 nm of physically vapor deposited (PVD) copper was washed with ethanol for five minutes and then placed in a reaction chamber at 300° C. The wafer was exposed to one minute of nitrogen plasma, and then 25 ALD cycles of sequential exposures to (dimethylamino)trimethoxysilane (5 seconds) and nitrogen plasma (10 seconds) separated by 10 second purges. Minimal silicon was detected on the copper surface by XPS. (see FIG. 5).

### Example 6: Selective Growth of SiO₂ on SiO₂ Using (Dimethylamino)trimethoxysilane

A silicon wafer a 1.7 nm thick native silicon dioxide layer was placed in a reaction chamber at 400° C. The wafer was exposed to one minute of nitrogen plasma, and then 125 ALD cycles of sequential exposures to (dimethylamino)trimethoxysilane (10 seconds), nitrogen plasma (10 seconds) and water (ten seconds) separated by 10 second purges. The thickness of the additional silicon dioxide film was determined to be 3.9 nanometers by ellipsometry, for a total of 5.6 nanometers of silicon dioxide.

### Example 7: Selective Non-Growth of SiO₂ on Cobalt Using (Dimethylamino)trimethoxysilane

A silicon wafer with 50 nm of physically vapor deposited (PVD) cobalt was placed in a reaction chamber at 400° C. The wafer was exposed to one minute of nitrogen plasma, and then 125 ALD cycles of sequential exposures to (dimethylamino)trimethoxysilane (10 seconds), nitrogen plasma (10 seconds) and water (ten seconds) separated by 10 second purges. The thickness of the resulting silicon dioxide film was determined to be 1.0 nanometer by XPS.

### Comparative Example 1: Non-Growth of Comparative Compound (N-methyl-aza-2,2,4-trimethylsilacyclopentane) Under Inventive Conditions

A silicon wafer with 1000 nm of thermal oxide was placed in a reaction chamber at 400° C. The wafer was exposed to one minute of nitrogen plasma, and then 125 ALD cycles of sequential exposures to a non-inventive chemical compound that does not comprise oxygen at positions R₁, R₂, or R₃ (N-methyl-aza-2,2,4-trimethylsilacyclopentane, 10 second exposure), nitrogen plasma (10 seconds), and water (10 seconds) separated by 10 second purges. Less than 0.6 nanometers of film growth was observed by ellipsometry (see FIG. 1).

### Comparative Example 2: Unselective Growth of N-ethyl-2,2-dimethoxy-4-methyl-1-aza-2-silacyclopentane on SiO₂ Under Comparative Conditions

A silicon wafer with 1000 nm of thermal oxide was placed in a reaction chamber at 30° C. The wafer was exposed to one minute of nitrogen plasma, and then 125 ALD cycles of sequential exposures to N-ethyl-2,2-dimethoxy-4-methyl-1-aza-2-silacyclopentane (5 seconds), oxygen plasma (10 seconds), separated by 10 second purges. A silicon dioxide film of 8.2 nm was grown on top of the underlying thermal oxide as determined by ellipsometry (see FIG. 1).

### Comparative Example 3: Unselective Growth of N-ethyl-2,2-dimethoxy-4-methyl-1-aza-2-silacyclopentane on Copper Under Comparative Conditions

A silicon wafer with 500 nm of PVD copper was washed with ethanol for five minutes and then placed in a reaction chamber at 30° C. The wafer was exposed to one minute of nitrogen plasma, and then 125 ALD cycles of sequential exposures to N-ethyl-2,2-dimethoxy-4-methyl-1-aza-2-silacyclopentane (5 seconds), oxygen plasma (10 seconds), separated by 10 second purges. A silicon dioxide film of approximately 10 nm was grown on top of the copper as determined by XPS depth profiling. The XPS depth profile data for the film of Comparative Example 3 shown in FIG. 3 demonstrates that silicon dioxide is deposited on copper when an oxidizing plasma is used rather than the inventive non-oxidizing plasma.

### Comparative Example 4: Unselective Growth of N-ethyl-2,2-dimethoxy-4-methyl-1-aza-2-silacyclopentane on Cobalt Under Comparative Conditions

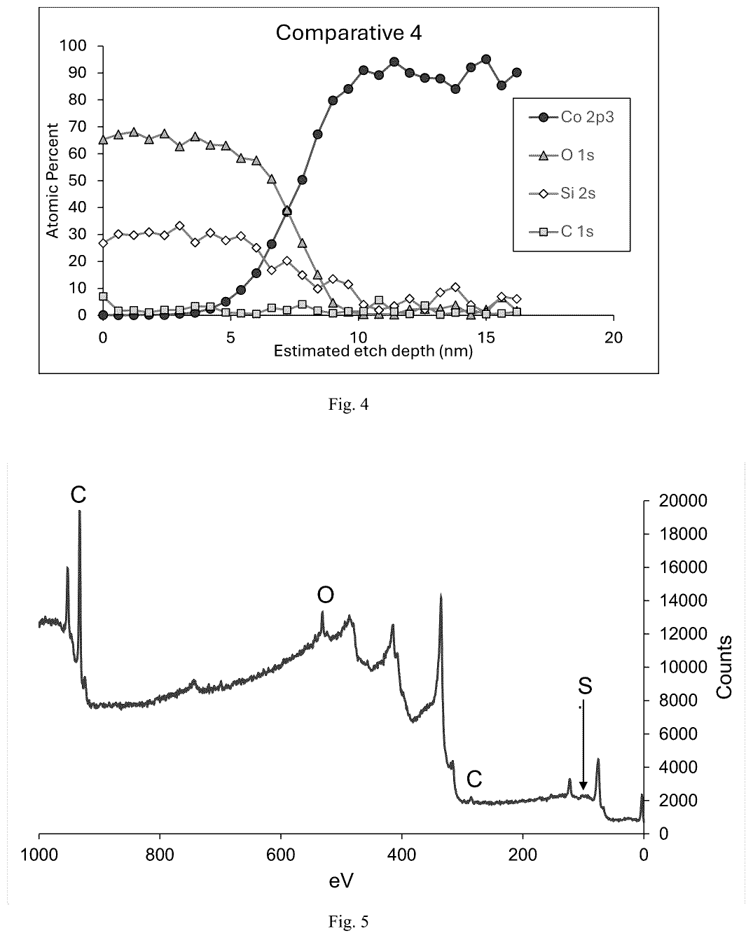

A silicon wafer with 50 nm of PVD cobalt was washed with ethanol for five minutes and then placed in a reaction chamber at 30° C. The wafer was exposed to one minute of nitrogen plasma, and then 125 ALD cycles of sequential exposures to N-ethyl-2,2-dimethoxy-4-methyl-1-aza-2-silacyclopentane (5 seconds), oxygen plasma (10 seconds), separated by 10 second purges. A silicon dioxide film of approximately 9 nm was grown on top of the cobalt as determined by XPS depth profiling. The XPS depth profile data for the film of Comparative Example 4 shown in FIG. 4 demonstrates that silicon dioxide is deposited on cobalt when an oxidizing plasma is used rather than the inventive non-oxidizing plasma.

### Comparative Example 5: Comparison of Precursors and Plasmas

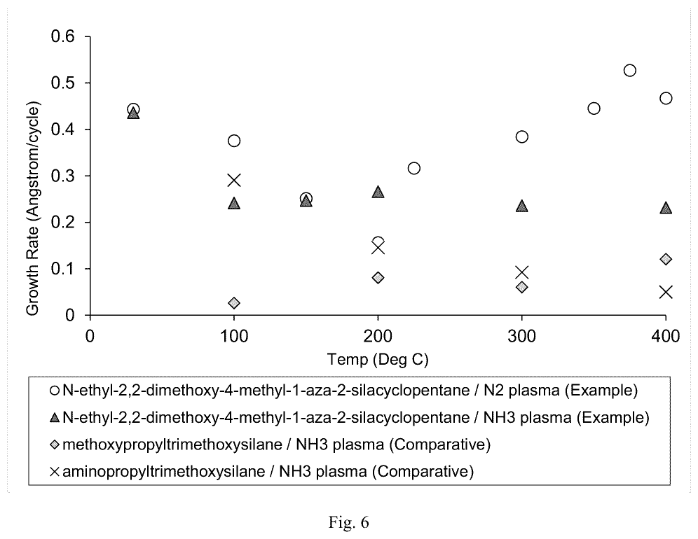

One inventive precursor (N-ethyl-2,2-dimethoxy-4-methyl-1-aza-2-silacyclopentane) and two comparative precursors (methoxypropyltrimethoxysilane and aminopropyltrimethoxysilane) were utilized in 25 cycle atomic layer deposition processes at temperatures ranging from 30° C. to 400° C., with a cycle comprising 5 seconds of exposure to precursor, ten seconds of nitrogen purge, ten seconds of plasma exposure, and ten seconds of purge. For the inventive precursor, experiments using both ammonia plasma and nitrogen plasma were conducted. For the comparative precursors, experiments were performed with ammonia plasma. The results are shown in FIG. 6.

FIG. 1 shows in-situ ellipsometry graphs for the films prepared in Example 1, Example 2, Comparative Example 1, and Comparative Example 2. The in-situ ellipsometry graphs shown in FIG. 1 demonstrate typical cyclic ALD growth for Examples 1 and 2. Additionally, Comparative Example 1, which utilized a comparative precursor structurally similar to that used in Example 1 but lacking an oxygen atom, and Comparative Example 2, which utilized the same precursor as Example 1 under non-inventive oxidizing plasma conditions, are shown.

FIG. 2 depicts X-ray photoelectron spectroscopy (XPS) data for the silicon 2s peaks for Example 1, Example 2, and Example 3. The X-ray photoelectron spectroscopy (XPS) data in FIG. 2 demonstrate a substantially complete selectivity for deposition on the thermal oxide surface with respect to the copper and cobalt surfaces.

FIG. 3 depicts the X-ray photoelectron spectra of Comparative Example 3, showing a thick layer of silicon dioxide growth on copper under non-inventive oxidizing plasma conditions.

FIG. 4 depicts the X-ray photoelectron spectra of Comparative Example 3, showing a thick layer of silicon dioxide growth on cobalt under non-inventive oxidizing plasma conditions.

FIG. 5 depicts the X-ray photoelectron spectra of Example 5, the near absence of silicon-related peaks demonstrating the high selectivity of the inventive process on a cobalt substrate.

FIG. 6 depicts the growth rate over 25 atomic layer deposition cycles for an inventive precursor (N-ethyl-2,2-dimethoxy-4-methyl-1-aza-2-silacyclopentane) and two comparative precursors (methoxypropyltrimethoxysilane and aminopropyltrimethoxysilane) as a function of temperature. Severe declines in growth rate were observed with the comparative precursors and ammonia plasma as the co-reactant, with growth rates at 200° C. and above falling below 0.2 Angstroms per cycle. Using the inventive precursor N-ethyl-2,2-dimethoxy-4-methyl-1-aza-2-silacyclopentane and ammonia plasma under otherwise identical conditions, growth rates between 0.2 and 0.3 Angstroms per cycle were observed. Using the same inventive precursor and nitrogen plasma further increased growth rates to as high as 0.5 Angstroms per cycle.

It will be appreciated by those skilled in the art that changes could be made to the embodiments described above without departing from the broad inventive concept thereof. It is understood, therefore, that this invention is not limited to the particular embodiments disclosed but it is intended to cover modifications within the spirit and scope of the present invention as defined by the appended claims.

We claim:

1. A method for selectively depositing a silicon-containing dielectric layer upon a patterned substrate, the method comprising:
(a) introducing a patterned substrate into a reaction zone of a deposition chamber, the patterned substrate comprising at least one metallic region and at least one isolated non-metallic region, where a temperature of the reaction zone is between about 25° C. and about 500° C.; and
(b) forming a silicon-containing dielectric layer overlaying only the at least one non-metallic region of the patterned substrate via an atomic layer deposition process or a chemical vapor deposition process, wherein the patterned substrate is exposed to a compound having Formula 1, Formula 2, Formula 3, or Formula 4, and wherein the patterned substrate is exposed to a non-oxidizing plasma: 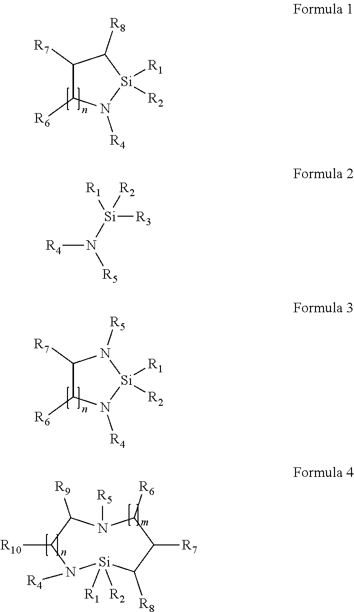
wherein n and m are each independently an integer from 1 to about 4; R₁, R₂, and R₃ are each independently a hydrogen or a linear, branched, or cyclic, optionally substituted, alkoxy, alkyl, aryl, alkyne, alkene, ether, ester, ketone, alkylamino, dialkylamino, alkyl(alkylamino), or alkyl(dialkylamino) group having 1 to about 12 carbon atoms; or a linear, branched, or cyclic, optionally substituted, silyl group having general formula SiR₁₁R₁₂R₁₃, OSiR₁₁R₁₂R₁₃, or R₁₄SiR₁₁R₁₂R₁₃, where R₁₁, R₁₂, and R₁₃ are each independently hydrogen or an alkyl or alkoxy group having about 1 to about 12 carbon atoms; and R₁₄ an linear or branched alkyl group having 1 to about 12 carbon atoms; R₄ and R₅ are each independently hydrogen; a linear, branched, or cyclic, optionally substituted, alkyl, aryl, alkyne, alkene, ether, ester, ketone, alkylamino, dialkylamino, alkyl(alkylamino), or alkyl(dialkylamino) group having 1 to about 12 carbon atoms; or a linear, branched, or cyclic, optionally substituted, silyl group having general formula SiR₁₁R₁₂R₁₃ or R₁₄SiR₁₁R₁₂R₁₃ where R₁₁, R₁₂, and R₁₃ are each independently hydrogen or an alkyl or alkoxy group having about 1 to about 12 carbon atoms; and R₁₄ an linear or branched alkyl group having 1 to about 12 carbon atoms; R₆, R₇, R₈, R₉ and R₁₀ are each independently hydrogen or a linear, branched, or cyclic, optionally substituted, alkoxy, alkyl, aryl, alkyne, alkene, ether, ester, ketone, alkylamino, dialkylamino, alkyl(alkylamino), or alkyl(dialkylamino) group having 1 to about 12 carbon atoms; or a linear, branched, or cyclic, optionally substituted, silyl group having general formula SiR₁₁R₁₂R₁₃, OSiR₁₁R₁₂R₁₃ or R₁₄SiR₁₁R₁₂R₁₃ where R₁₁, R₁₂, and R₁₃ are each independently hydrogen or an alkyl or alkoxy group having about 1 to about 12 carbon atoms; and R₁₄ an linear or branched alkyl group having 1 to about 12 carbon atoms; and at least one of R₁, R₂ and R₃ comprises at least one oxygen atom.

2. The method according to claim 1, wherein the patterned substrate is exposed to the compound having Formula 1, Formula 2, Formula 3, or Formula 4, and to the non-oxidizing plasma simultaneously.

3. The method according to claim 1, wherein the patterned substrate is exposed to the compound having Formula 1, Formula 2, Formula 3, or Formula 4, and to the non-oxidizing plasma sequentially.

4. The method according to claim 1, further comprising prior to step (b): performing an anneal, clean, etch, or plasma treatment on the patterned substrate.

5. The method according to claim 1, further comprising prior to step (b): exposing the patterned substrate to a chemical blocking agent to selectively passivate at least one region of the substrate.

6. The method according to claim 1, wherein a source gas for the non-oxidizing plasma comprises hydrogen, nitrogen, ammonia, or hydrazine.

7. The method according to claim 1, wherein a source gas for the non-oxidizing plasma comprises less than about one volume percent oxygen, hydrogen peroxide, carbon dioxide, water, or nitrous oxide.

8. The method according to claim 1, wherein the compound of Formula 1, Formula 2, Formula 3, or Formula 4 is N-ethyl-2,2-dimethoxy-4-methyl-1-aza-2-silacyclopentane, N-n-butyl-aza-2,2-dimethoxysilacyclopentane, N-t-butyl-aza-2,2-dimethoxysilacyclopentane, N-methyl-aza-2,2-dimethoxysilacyclopentane, 2,2-dimethoxy-1,3-dimethyl-1,3-diaza-2-silacyclopentane, 2,2-diethoxy-1,3-dimethyl-1,3-diaza-2-silacyclopentane, (1-(3-triethoxysilyl)propyl)-2,2-diethoxy-1-aza-2-silacyclopentane, N-allyl-aza-2,2-dimethoxysilacyclopentane, 2,2-dimethoxy-1,6-diaza-2-silacyclooctane, aza-2-methyl-2-methoxysilacyclopentane, N-methyl-2-methyl-2-methoxy-4-methyl-1-aza-2-silacyclopentane, (dimethylamino)trimethoxysilane, (diethylamino)trimethoxysilane, (diethylamino)triethoxysilane, (dimethylamino)triethoxysilane, (diisopropoxyamino)trimethoxysilane, or (diisopropoxyamino)triethoxysilane, bis(dimethylamino)dimethoxysilane, bis(dimethylamino)diethoxysilane, tris(dimethylamino)methoxysilane, tris(dimethylamino)ethoxysilane, 3-[(dimethylamino)dimethylsilyl]propyl 2-methyl-2-propenoate, 2-(ethoxymethyl)-1-(trimethylsilyl)-1-aza-2-silacyclopentane, 1-(3-methoxypropyl)-N,N, 1,1-tetramethylsilanamine, or N-methyl-2,2-dimethoxy-4-trimethylsilyl-1-aza-2-silacyclopentane, or 2-methoxy-1-(trimethylsilyl)-2-[(trimethylsilyl)oxy]-1-aza-2-silacyclopentane.

9. The method according to claim 1, wherein the silicon-containing dielectric layer has a thickness of about 1 nm to about 20 nm.

10. The method according to claim 9, wherein the silicon-containing dielectric layer has a thickness of about 3 nm to about 10 nm.

11. The method according to claim 1, wherein the temperature of the reaction chamber is about 275° C. to about 425° C.

12. The method according to claim 1, wherein the patterned substrate comprises silicon dioxide, silicon oxycarbide, silicon oxynitride, silicon carboxynitride, silicon oxyfluoride, or borosilicate.

13. The method according to claim 1, wherein the silicon-containing dielectric layer has a film thickness of less than about 1 nm on at least one area of the patterned substrate comprising copper, cobalt, ruthenium, molybdenum, tungsten, and/or gold.

14. The method according to claim 1, where an atomic layer deposition process is used to form the silicon-containing dielectric layer.

15. The method according to claim 14, where the atomic layer deposition process comprises:
(b1) exposing the patterned substrate to a pulse of the compound of Formula 1, Formula 2, Formula 3, or Formula 4;
(b2) purging the deposition chamber;
(b3) exposing the patterned substrate to the non-oxidizing plasma;
(b4) purging the deposition chamber; and
(b5) repeating steps (b1) to (b4) until a desired layer thickness is reached.

16. The method according to claim 15, further comprising prior to step (b1) performing at least one of the following steps:
(b0.1) performing an anneal, clean, etch, or plasma treatment on the patterned substrate;
(b0.2) exposing the patterned substrate to an oxidant; and
(b0.3) exposing the patterned substrate to a chemical blocking agent to selectively passivate at least one region of the substrate.

17. The method according to claim 15, further comprising after step (b4):
(b4.1) exposing the patterned substrate to a pulse of an oxidant; and
(b4.2) purging the deposition chamber.

18. The method of claim 17, where the oxidant is selected from water, carbon dioxide, nitrous oxide, oxygen, ozone, hydrogen peroxide, alcohols, mixtures thereof, and plasmas thereof.

19. The method according to claim 15, further comprising after step (b5) performing at least one of the following steps (b5.1) to (b5.3):
(b5.1) performing an anneal, clean, etch, or plasma treatment on the patterned substrate;
(b5.2) exposing the patterned substrate to an oxidant;
(b5.3) exposing the patterned substrate to a chemical blocking agent to selectively passivate at least one region of the substrate; and then
(b5.4) optionally purging the reaction chamber; and
(b6) repeating steps b (1) through (b5) at least one time.

20. The method according to claim 14, wherein the pulse of the compound of Formula 1, Formula 2, Formula 3, or Formula 4 has a duration of about 0.05 seconds to about 30 seconds.

21. The method according to claim 20, wherein the pulse of the compound of Formula 1, Formula 2, Formula 3, or Formula 4 has a duration of about 5 seconds to about 10 seconds.

22. The method according to claim 14, wherein the patterned substrate is exposed to the non-oxidizing plasma for about 1 second to about 60 seconds.

23. The method according to claim 22, wherein the patterned substrate is exposed to the non-oxidizing plasma for about 10 seconds to about 20 seconds.

24. The method according to claim 1, wherein a chemical vapor deposition process or pulsed chemical vapor deposition process is used to form the silicon-containing dielectric layer.

25. The method according to claim 24, wherein the chemical vapor deposition or pulsed chemical vapor deposition process comprises:
(b7) exposing the patterned substrate to the compound of Formula 1, Formula 2, Formula 3, or Formula 4 while simultaneously exposing the patterned substrate to a non-oxidizing plasma until a desired layer thickness is reached;
(b8) optionally purging the deposition chamber; and
(b9) repeating steps (b7) and (b8) until a second desired layer thickness is reached.

26. The method according to claim 25, further comprising after step (b8) performing at least one of the following steps:
(b8.1) performing an anneal, clean, etch, or plasma treatment on the patterned substrate;
(b8.2) exposing the patterned substrate to an oxidant;
(b8.3) exposing the patterned substrate to a chemical blocking agent to selectively passivate at least one region of the substrate;
and then
(b8.4) optionally purging the reaction chamber.

27. The method according to claim 25, further comprising prior to step (b7) performing at least one of the following steps:
(b0.1) performing an anneal, clean, etch, or plasma treatment on the patterned substrate;
(b0.2) exposing the patterned substrate to an oxidant;
(b0.3) exposing the patterned substrate to a chemical blocking agent to selectively passivate at least one region of the substrate.
